(19) United States
(12) Patent Application Publication
(10) Pub. No.: US 2020/0081158 A1
(43) Pub. Date: Mar. 12, 2020

(54) Texture Structure, Optical Film, Mold and Cover Plate for Electronic Device

(71) Applicant: Shine Optoelectronics (Kunshan) Co., Ltd., Kunshan City (CN)

(72) Inventors: Shen Hong, Kunshan City (CN); Yulong Gao, Kunshan City (CN); Hongwei Kang, Kunshan City (CN); Su Shen, Kunshan City (CN)

(21) Appl. No.: 16/686,032

(22) Filed: Nov. 15, 2019

Related U.S. Application Data
(63) Continuation of application No. PCT/CN2018/087061, filed on May 16, 2018.

(30) Foreign Application Priority Data
May 16, 2017 (CN) 201710344758.0

(51) Int. Cl. G02B 1/10; H04M 1/02; H05K 5/03; B29C 33/38

(52) U.S. Cl. CPC G02B 1/10; B29C 33/3857; H05K 5/03; H04M 1/02

(57) ABSTRACT

A texture structure, an optical film, a mold and a cover plate for an electronic device. The texture structure includes a certain number of small short lines, there existing an included angle between at least one of the small short lines and the horizontal direction, at least one of the small short lines being of a convex structure or a concave structure; wherein intervals are provided between neighboring small short lines. The texture structure can change the directions of the small short lines randomly or according to a wanted effect in a certain direction. The optical film with the texture structure, wherein there exists at least one light pillar in the optical film with such a texture structure under a certain light source. The cover plate for an electronic device adopts the texture structure or the optical film.

### CROSS REFERENCE TO RELATED APPLICATION

This application is a continuation of International Application No. PCT/CN2018/087061, which designates the United States and was filed on May 16, 2018, published in Chinese, which claims priority to Chinese Patent Application No. 201710344758.0, entitled “Patterned Structure, Optical Film, Mold, and Electronic Device Cover,” filed on May 16, 2017. The entire teachings of the above applications are incorporated herein by reference.

### TECHNICAL FIELD

This disclosure relates to the fields of texture, optical film and cover plate for a device, and in particular to a texture structure, an optical film, a mold and a cover plate for an electronic device.

### BACKGROUND ART

With the development of sciences and technologies, decorative films are widely used in surfaces of electronic products, such as mobile phones, and computers, etc., household appliances, such as refrigerators, air conditioners, washing machines, etc., and other products, such as vehicles, etc.

Existing decorative films are used as surface materials of mobile machined, such as mobile phones, and notebook computers, etc., and are used as surface materials for molding household appliances, such as refrigerators, washing machines, air conditioners, etc., although a variety of patterns and metal textures are embodied by gravure printing.

Existing decorative textures are generally cylindrical mirrors or printed patterns. The resolution of printed patterns is not very high. And use of cylindrical mirrors generally produces rainbow patterns that interfere with effects of the cylindrical mirrors, hence, there is need for developing a new decorative texture.

### SUMMARY OF THE INVENTION

Due to the above reasons, there is a need to provide a texture structure, an optical film and a cover plate for an electronic device, so as to solve the above technical problems.

A technical solution of this disclosure is as follows.

A texture structure, wherein the texture structure comprises a certain number of small short lines, there existing an included angle between at least one of the small short lines and the horizontal direction;

at least one of the small short lines being of a convex structure or a concave structure; wherein there exist at least one pair of neighboring small short lines with an interval therebetween.

In an embodiment, there are included angles a and b between at least two small short lines and the horizontal direction, the included angle a being unequal to the included angle b.

In an embodiment, the certain number of small short lines are arranged in an arrangement of a predetermined form.

In an embodiment, the arrangement of a predetermined form is linear or substantially linear.

In an embodiment, a cross section of a small short line is of one of an arc, a trapezoid, a triangle, a quadrilateral, a shape with at least one side being of an arc, and a polygon.

An optical film, wherein it comprises:

a polymer layer;

a certain number of small short lines, the certain number of small short lines being formed at a side of the polymer layer and forming a micro-nano structure;

wherein at least one of the small short lines is of a convex structure or a concave structure.

In an embodiment, there exists an included angle between at least one of the small short lines and the horizontal direction.

In an embodiment, there are included angles a and b between at least two small short lines and the horizontal direction, the included angle a being unequal to the included angle b.

In an embodiment, the certain number of small short lines are arranged in an arrangement of a predetermined form.

In an embodiment, the arrangement of a predetermined form is linear or substantially linear.

In an embodiment, there exist intervals between neighboring small short lines, the interval being 5 μm-50 μm.

In an embodiment, a distance between a bottom of the convex structure or concave structure of the small short lines and a surface at the other side of the polymer layer is 0.05 μm-200 μm.

In an embodiment, there exist at least two small short lines with identical heights or depths in the small short lines.

In an embodiment, there exist at least two small short lines with a height difference or a depth difference greater than 0.05 μm and not greater than 2 μm in the small short lines.

In an embodiment, there exist at least two small short lines with a height difference or a depth difference greater than 2 μm and less than 100 μm in the small short lines.

In an embodiment, there exist at least two small short lines with identical widths in the small short lines.

In an embodiment, there exist at least two small short lines with a width difference greater than 0.05 μm and not greater than 3 μm in the small short lines.

In an embodiment, there exist at least two small short lines with a width difference greater than 3 μm and less than 100 μm in the small short lines.

In an embodiment, a reflective layer is disposed at the side of the polymer layer where the small short lines are disposed.

In an embodiment, a colored layer is disposed at a side of the reflective layer away from the small short lines.

In an embodiment, a carrier layer is disposed at the other side of the polymer layer.

In an embodiment, an adhesive layer is disposed between the polymer layer and the carrier layer.

A mold for manufacturing an optical film, wherein the mold comprises:

a carrier body;

a polymer layer disposed at one side of the carrier body;

a certain number of small short lines, the certain number of small short lines being formed at a side of the polymer layer away from the carrier body and forming a micro-nano structure;

wherein at least one of the small short lines is of a convex structure or a concave structure.

A cover plate for an electronic device, wherein the cover plate for an electronic device comprises the texture structure as described in any one of above embodiments.

A cover plate for an electronic device, wherein the cover plate for an electronic device comprises the optical film as described in any one of above embodiments.

Advantages of this disclosure exist in that:

(I) this application provides a new texture structure, in which directions of the small short lines may be changed randomly or according to a wanted effect in a certain direction, and included angles between the small short lines and the horizontal direction may vary from 0 degree to 180 degrees;

(II) this application provides an optical film with the texture structure, there existing at least one light pillar in the optical film with such a texture structure under a certain light source, which may reduce influence of a rainbow texture to the light shadow effects to some extent;

(III) this application provides a cover plate for an electronic device, the cover plate for an electronic device adopting the texture structure or the optical film, which may achieve different light shadow effects of the cover plate for an electronic device by flexibly applying rotation angles of the small short lines.

### BRIEF DESCRIPTION OF THE DRAWINGS

FIG. 1 is a schematic diagram of a structure of the cover plate for an electronic device of this disclosure;

FIG. 2 is schematic diagram of one of the structure of the arrangement of the texture structure of this disclosure;

FIG. 3 is a schematic diagram of a structure of the texture structure of this disclosure;

FIG. 4 is schematic diagram of a structure of the optical film including the texture structure of this disclosure;

FIG. 5 is a schematic diagram of a cross-sectional structure of the optical film of this disclosure;

FIG. 6 is a schematic diagram of a cross-sectional structure of the optical film of this disclosure;

FIG. 7 is another schematic diagram of the cross-sectional structure of the optical film of this disclosure;

FIG. 8 is a schematic diagram of a cross-sectional structure of the optical film of this disclosure;

FIG. 9 is a schematic diagram of a cross-sectional structure of the optical film of this disclosure;

FIG. 10 is another schematic diagram of the cross-sectional structure of the optical film of this disclosure;

FIG. 11 is a further schematic diagram of the cross-sectional structure of the optical film of this disclosure;

FIG. 12 is yet a further schematic diagram of the cross-sectional structure of the optical film of this disclosure;

FIG. 13 is yet a further schematic diagram of the cross-sectional structure of the optical film of this disclosure;

FIG. 14 is yet a further schematic diagram of the cross-sectional structure of the optical film of this disclosure;

FIG. 15 is schematic diagram of a cross-sectional structure of the mold for manufacturing an optical film of this disclosure.

### DETAILED DESCRIPTION OF THE INVENTION

For this disclosure to be understood, this disclosure shall be fully described below with reference to the accompanying drawings. Better embodiments of this disclosure are given in the accompanying drawings; however, this disclosure may be carried out in various ways, which are not limited to those described below. Rather, these embodiments are provided so that the contents disclosed in this disclosure are understood more thoroughly and completely.

It should be noted that when an element is referred to as “being disposed on” another element, the element may be directly on the other element, or there exists an intermediate element therebetween. When an element is deemed as “being connected to” another element, the element may be directly connected to the other element, or there exists an intermediate element therebetween at the same time. The terms “vertical”, “horizontal”, “left”, “right”, and other similar expressions are only aimed at describing, and are not intended to show a unique embodiment.

All technical and scientific terms used herein have the same meanings as commonly understood by those skilled in the art to which this disclosure pertains, unless otherwise defined. The terminology used in the description of this disclosure is for the purpose of describing particular embodiments and is not intended to limit this disclosure. The term “and/or” as used herein includes any and all combinations of one or more of the associated listed items.

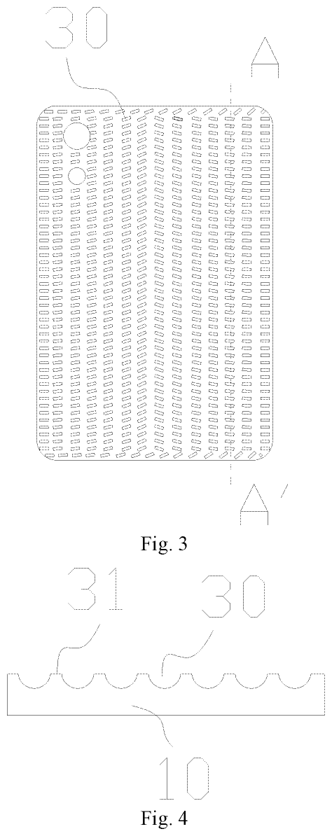

Referring to FIG. 3, in which a texture structure is disclosed, wherein the texture structure includes a certain number of small short lines 30, there existing an included angle between at least one of the small short lines 30 and the horizontal direction, that is, at least one of the small short lines 30 is rotated in an arrangement process, and there exists an included angle between the small short line and the horizontal direction.

At least one of the small short lines 30 is of a convex structure or a concave structure. The small short lines 30 may be disposed as convex structures, or concave structures, or partial convex structures and partial concave structures, on an arrangement plane of the small short lines 30; wherein there exist at least one pair of neighboring small short lines with an interval therebetween. The interval here refers to that a point is taken respectively from two neighboring small short lines, the two points are connected by a straight line, and there exist an area in the straight line that is not covered by the small short lines 30.

In an embodiment, there are included angles a and b between at least two small short lines and the horizontal direction, the included angle a being unequal to the included angle b. The small short lines may be rotated at one angle (that is, included angles between all the small short lines and the horizontal direction are all identical), or, the small short lines may be rotated at different angles, hence, included angles between the small short lines 30 and the horizontal direction may be different.

In an embodiment, referring to FIG. 2, the certain number of small short lines are arranged in an arrangement of a predetermined form. The arrangement of a predetermined form is linear 20 or substantially linear 20, and they may be arranged in different forms as demanded.

In an embodiment, a cross section of a small short line 30 is of one of an arc, a trapezoid, a triangle, a quadrilateral, a shape with at least one side being of an arc, and a polygon.

Referring to FIG. 4, an optical film, wherein it includes:

a polymer layer 10, which may be of a general polymer material, or a thermosetting material, or a light-cured material;

a certain number of small short lines 30, the certain number of small short lines 30 being formed at a side of the polymer layer 10 and forming a micro-nano structure, and the micro-nano structure being integral with the polymer layer 10;

wherein at least one of the small short lines 30 is of a convex structure, and there exists an interval 31 between at least a pair of neighboring small short lines 30. Referring to FIG. 7, at least one of the small short lines 32 given in FIG. 7 is of a convex structure, and there exists an interval 33 between at least a pair of neighboring small short lines 32.

In an embodiment, referring to FIGS. 4, 7 and 10-14, there exists an included angle between at least one of the certain number of small short lines 30, 32, 34, 35, 36, 37, 38 and the horizontal direction.

In an embodiment, referring to FIGS. 4, 7 and 10-14, there are included angles a and b between at least two small short lines of the certain number of small short lines 30, 32, 34, 35, 36, 37, 38 and the horizontal direction, the included angle a being unequal to the included angle b.

Small short line texture structures are disposed on the optical film, and according to different optical effects to be achieved, angles of the certain number of small short lines 30, 32, 34, 35, 36 and 37 may be rotated, so that they exhibit different angles, and desired effects may be achieved.

In an embodiment, the certain number of small short lines are arranged in an arrangement of a predetermined form. In an embodiment, the arrangement of a predetermined form is linear or substantially linear, and the small short lines may also be arranged in other forms.

In an embodiment, referring to FIGS. 4 and 7, there exist intervals between neighboring small short lines, the interval 31 or 33 d being 5 μm-50 μm. Such a range of intervals may well control human eyes to distinguish intervals between the small short lines, thereby affecting visual effects.

In an embodiment, referring to FIGS. 4 and 7, the small short line 30 in FIG. 4 is of a concave structure, and the small short line 32 in FIG. 7 is of a convex structure, and at this moment, a distance between a bottom of the concave structure of the small short line 30 and a surface at the other side of the polymer layer is 0.05 μm-200 μm, and a distance between a bottom of the convex structure of the small short line 32 and the surface at the other side of the polymer layer is 0.05 μm-200 μm, corresponding to a distance between an uttermost bottom of the texture in a process of manufacturing the small short line 30 or 32 and a residual adhesive at the other side.

In an embodiment, referring to FIG. 7, there exist at least two small short lines with identical heights h1 and h2 in the certain number of small short lines 32, and referring to FIG. 4, there exist at least two small short lines with identical depths in the certain number of small short lines 30.

In an embodiment, referring to FIG. 7, there exist at least two small short lines with a height difference, i.e. a difference between h1 and 2, greater than 0.05 μm and not greater than 2 μm in the certain number of small short lines 32, and referring to FIG. 4, there exist at least two small short lines with a depth difference greater than 0.05 μm and not greater than 2 μm in the certain number of small short lines 30.

Such a design may lower a difficulty in the process, and may achieve desired optical effect. And as there exist relatively small height differences, the optical effects are hard to be seen by human eyes. The height differences and depth differences here are provided on the premise that the area or circumference of the plane where there exist convexities or concaves is substantially changeless.

In an embodiment, referring to FIG. 10, the small short lines 34 and 35 are of convex structures, and there exist at least two small short lines 34 and 35 with a height difference, i.e. a difference between h3 and h4, greater than 2 μm and less than 100 μm in the certain number small short lines; and when the small short lines are of concave structures, there exist at least two small short lines with a depth difference greater than 2 μm and less than 100 μm in the certain number small short lines.

Here, the height difference between the convexities or the depth differences between the concaves of the small short lines are set relatively large, and such a setting may bring different visual effects, so that the visual effects of the optical film is better and richer, and adaptation of needs of different users may be increased, bringing customers more senses of changes.

In an embodiment, referring to FIG. 7, at least two small short lines in the certain number of small short lines 32 have identical widths. Here, two small short lines are defined to have identical widths but their heights may be identical or different.

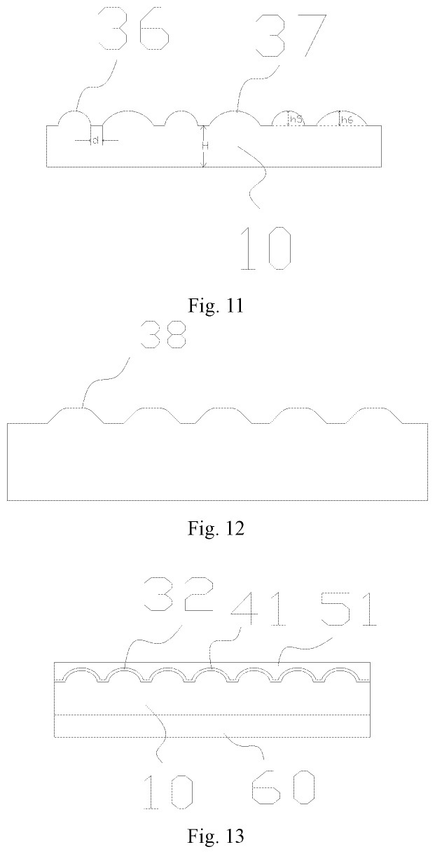

In an embodiment, referring to FIG. 11, at least two small short lines 36 and 37 in the certain number of small short lines have a width difference greater than 0.05 μm and not more than 3 μm, and heights h5 and h6 of the two small short lines in FIG. 11 are roughly identical. Such a design lower a difficulty of the process and may achieve the desired optical effects, as there exist relatively small width differences, the optical effects are hard to be perceived by human eyes.

In an embodiment, referring to FIG. 11, at least two small short lines 36 and 37 of the certain number of small short lines have a width difference greater than 3 μm and less than 100 μm. Here, the width difference of the small and short lines is set relatively large. Such a setting may bring different visual effects, so that the visual effects of the optical film is better and richer, and adaptation of needs of different users may be increased, bringing customers more senses of changes.

In an embodiment, referring to FIG. 12, a cross section of the small short line 38 is of a trapezoidal shape or an approximately trapezoidal shape.

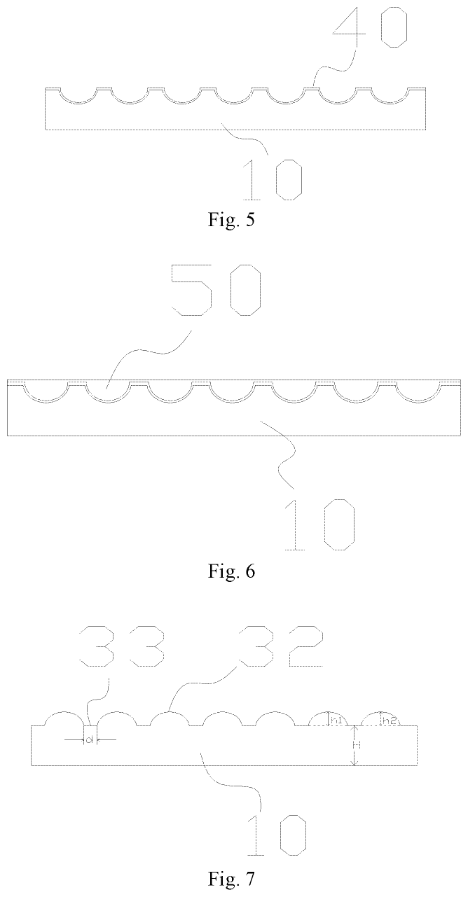

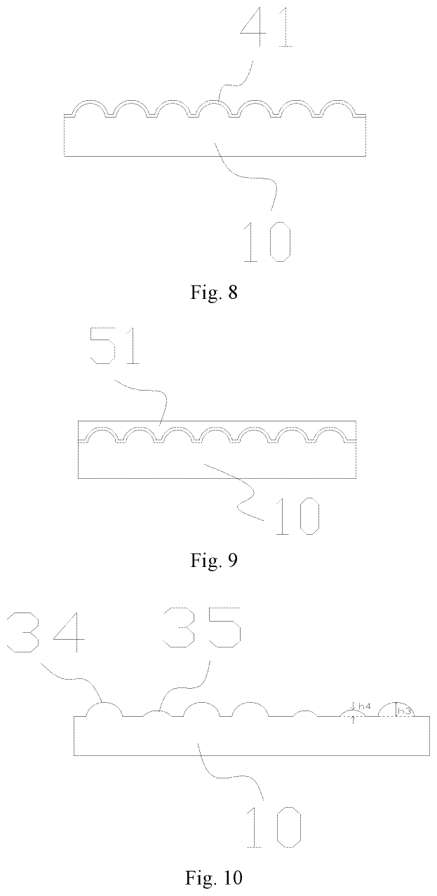

In an embodiment, referring to FIGS. 5 and 8, the polymer layer is further provided with reflective layers 40, 41 at side at which the small short lines are provided. The reflective layers 40, 41 may function to mix color and/or reflect, and when a colored polymer is selected as the material of the polymer layer, the reflective layers 40, 41 may only function to reflect, and may also function to mix color together with the colored polymer.

In an embodiment, referring to FIGS. 6 and 9, the side of the reflective layers 40, 41 away from the small short lines is further provided with colored layers 50, 51. The colored layers 50, 51 may be colored inks, which may function as backing, and may also function as color mixing between the colored inks and the reflective layers.

In an embodiment, referring to FIG. 13, which may be a cross-sectional view in a direction of A-A′ in FIG. 3, and may be a partial hierarchical structure, or may be a cross section of the cover plate. The other side of the polymer layer 10 is further provided with a carrier layer 60, which may be of a substrate material, such as PET, PC, PMMA, or the like, or may be of another substrate material, such as glass, metal, or sapphire, or the like.

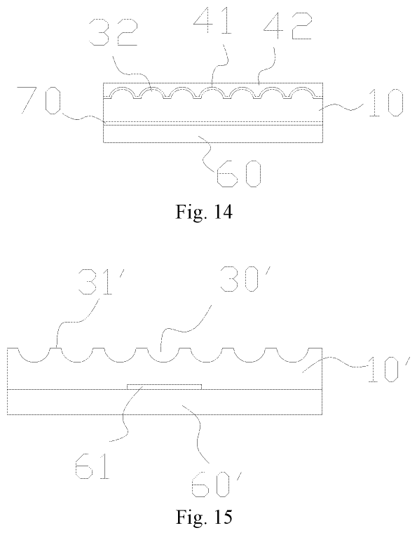

In an embodiment, referring to FIG. 14, an adhesive layer 70 is disposed between the polymer layer 10 and the carrier layer 60. FIG. 14 may be a cross-sectional view in the direction of A-A′ in FIG. 3, which may be a partial layer structure, or may be a cross section of the cover plate. The carrier layer 60 may be of a substrate material, such as PET, PC, PMMA, or the like, or may be of another substrate material, such as glass, metal, or sapphire, or the like.

Referring to FIG. 15, a mold for manufacturing an optical film, wherein the mold includes:

a carrier body 60′;

a polymer layer 10′ disposed at one side of the carrier body 60′;

a certain number of small short lines, the certain number of small short lines 30′ being formed at a side of the polymer layer 10′ away from the carrier body 60′ and forming a micro-nano structure;

wherein at least one of the small short lines 30′ is of a convex structure or a concave structure; what is given in the figure is a concave structure, of course, it may also be a convex structure; and furthermore, a blocking layer 61 is provided between the carrier body 60′ and the polymer layer 10′. In this way, some area do not need textures during a process of imprinting by the mold, and as the blocking layer 61 is used, areas that are blocked will not be cured during a process of curing.

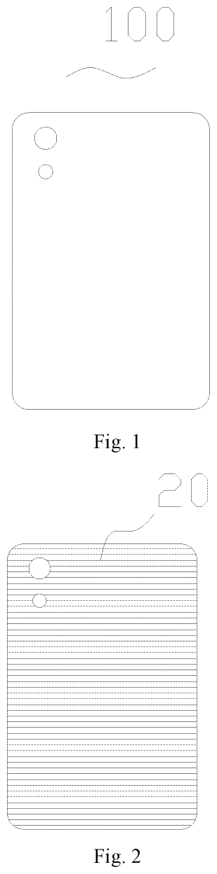

Referring to FIG. 1, a cover plate for an electronic device, wherein the cover plate for an electronic device at least includes the small short line texture structure shown in FIG. 3, and may further include superimposition of other texture structures, the other texture structures being cylindrical mirrors, CD textures, Fresnel lenses, or drawn textures, etc.

Referring to FIG. 1, a cover plate for an electronic device, wherein the cover plate for an electronic device at least includes the optical film as shown in FIGS. 4-13.

The electronic device may be a 3C product or a household appliance; wherein the 3C product includes: a mobile phone, a PAD, a watch, a computer, an iPOD, a camera, etc., and the household appliance includes: a refrigerator, a television set, an air conditioner, a washing machine, and the like.

The technical solution of this disclosure at least includes the following advantages:

(I) this application provides a new texture structure, in which directions of the small short lines may be changed randomly or according to a wanted effect in a certain direction, and included angles between the small short lines and the horizontal direction may vary from 0 degree to 180 degrees;

(II) this application provides an optical film with the texture structure, there existing at least one light pillar in the optical film with such a texture structure under a certain light source, which may reduce influence of a rainbow texture to the light shadow effects to some extent;

(III) this application provides a cover plate for an electronic device, the cover plate for an electronic device adopting the texture structure or the optical film, which may achieve different light shadow effects of the cover plate for an electronic device by flexibly applying rotation angles of the small short lines.

For the above targets, features and advantages of the present invention to be understood more easily, embodiments of the present inventions are described above with reference to the accompanying drawings. In the above description, many details are given so that the present invention is fully understood. However, the present invention may be carried out in other implementations than those described above. Similar modifications may be made by those skilled in the art without departing from the concept of the present invention, hence, the present invention is not limited to the above disclosure. And the technical features of the above embodiments may be arbitrarily combined. For the sake of concise description, not all possible combinations of the technical features of the above embodiments are described. However, combinations of the technical features shall be deemed as being within the protection scope of the present invention only if the combinations of these technical features are not contradictory to each other.

The above embodiments are some implementations of the present invention only. Description of these implementations are relatively particular and minute, however, it should not be understood as limiting the protection scope of the present invention. It should be noted that many variants and modifications may be made by those skilled in the art without departing from the concept of the present invention, and all of these are covered by the present invention. Hence, the protection scope of the present invention shall be covered by the attached claims.

What is claimed is:

1. A texture structure, the texture structure comprises a certain number of small short lines, there existing an included angle between at least one of the small short lines and the horizontal direction;
at least one of the small short lines being of a convex structure or a concave structure; wherein there exist at least one pair of neighboring small short lines with an interval therebetween.

2. The texture structure according to claim 1, wherein there are included angles a and b between at least two small short lines and the horizontal direction, the included angle a being unequal to the included angle b.

3. The texture structure according to claim 1, wherein the certain number of small short lines are arranged in an arrangement of a predetermined form.

4. The texture structure according to claim 1, wherein a cross section of a small short line is of one of an arc, a trapezoid, a triangle, a quadrilateral, a shape with at least one side being of an arc, and a polygon.

5. An optical film, it comprises:
a polymer layer;
a certain number of small short lines, the certain number of small short lines being formed at a side of the polymer layer and forming a micro-nano structure;
wherein at least one of the small short lines is of a convex structure or a concave structure.

6. The optical film according to claim 5, wherein there exists an included angle between at least one of the certain number of small short lines and the horizontal direction.

7. The optical film according to claim 6, wherein there are included angles a and b between at least two small short lines and the horizontal direction, the included angle a being unequal to the included angle b.

8. The optical film according to claim 5, wherein the certain number of small short lines are arranged in an arrangement of a predetermined form.

9. The optical film according to claim 8, wherein the arrangement of a predetermined form is linear or substantially linear.

10. The optical film according to claim 5, wherein there exist intervals between neighboring small short lines, the interval being 1 μm-500 μm.

11. The optical film according to claim 5, wherein a distance between a bottom of the convex structure or concave structure of the small short lines and a surface at the other side of the polymer layer is 0.05 μm-200 μm.

12. The optical film according to claim 5, wherein there exist at least two small short lines with identical heights or depths in the small short lines.

13. The optical film according to claim 5, wherein there exist at least two small short lines with a height difference or a depth difference greater than 0.05 μm and not greater than 2 μm in the small short lines.

14. The optical film according to claim 5, wherein there exist at least two small short lines with a height difference or a depth difference greater than 2 μm and less than 100 μm in the small short lines.

15. The optical film according to claim 5, wherein there exist at least two small short lines with identical widths in the small short lines.

16. The optical film according to claim 5, wherein there exist at least two small short lines with a width difference greater than 0.05 μm and not greater than 3 μm in the small short lines.

17. The optical film according to claim 5, wherein there exist at least two small short lines with a width difference greater than 3 μm and less than 300 μm in the small short lines.

18. The optical film according to claim 5, wherein a reflective layer is disposed at the side of the polymer layer where the small short lines are disposed, a colored layer is disposed at a side of the reflective layer away from the small short lines.

19. A mold for manufacturing an optical film, the mold comprises:
a carrier body;
a polymer layer disposed at one side of the carrier body;
a certain number of small short lines, the certain number of small short lines being formed at a side of the polymer layer away from the carrier body and forming a micro-nano structure;
wherein at least one of the small short lines is of a convex structure or a concave structure.

20. A cover plate for an electronic device, the cover plate for an electronic device comprises the optical film as claimed in claim 5.
